(19) United States
(12) Patent Application Publication
(10) Pub. No.: US 2025/0100014 A1
(43) Pub. Date: Mar. 27, 2025

(54) METHOD AND SYSTEM FOR PROVIDING A RELIABLE ISOLATION STACK IN CAPACITIVE MICROMACHINED ULTRASONIC TRANSDUCERS

(71) Applicant: GE Precision Healthcare LLC, Waukesha, WI (US)

(72) Inventors: Rupak Bardhan Roy, Nice (FR); Alessandro Stuart Savoia, Rome (IT)

(21) Appl. No.: 18/373,442

(22) Filed: Sep. 27, 2023

(51) Int. Cl. B06B 1/02; B81C 1/00

(52) U.S. Cl. CPC B06B 1/0292; B81C 1/00071; B81C 2201/0178

(57) ABSTRACT

Methods and systems for providing a reliable (i.e., defect mitigated) isolation stack in capacitive micromachined ultrasonic transducers (CMUTs) are disclosed. A capacitive micromachined ultrasonic transducer (CMUT) includes a top electrode and a bottom electrode. The CMUT includes a sidewall between the top electrode and the bottom electrode. The sidewall is configured to separate the top electrode and the bottom electrode by a gap. The CMUT includes an isolation stack part on one or both of a bottom side of the top electrode or a top side of the bottom electrode. The isolation stack part includes a silicon dioxide layer, and a partially oxidized silicon nitride comprising a silicon nitride layer and an oxidized nitride layer.

### FIELD

Certain embodiments relate to ultrasound imaging. More specifically, certain embodiments relate to methods and systems for providing a reliable (i.e., defect mitigated) isolation stack in capacitive micromachined ultrasonic transducers (CMUTs).

### BACKGROUND

An ultrasound device may be used for imaging targets such as organs and soft tissues in a human body, as well non-human targets. For example, an ultrasound device may be used for applications such as ultrasound/acoustic sensing, non-destructive evaluation (NDE), ultrasound therapy (e.g., High Intensity Focused Ultrasound (HIFU)), etc., in addition to ultrasound imaging of humans, animals, and the like.

Ultrasound devices may use real time, non-invasive high frequency sound waves to produce a series of two-dimensional (2D) and/or three-dimensional (3D) images. The sound waves may be transmitted by a transmit transducer, and the reflections of the transmitted sound waves may be received by a receive transducer. The received sound waves may then be processed to display an image of the target. A capacitive micromachined ultrasonic transducer (CMUT) that is used as a transmit transducer and/or a receive transducer may comprise a top electrode and a bottom electrode, where the top electrode may move due to electrical signals to generate sound waves, or move due to receiving sound waves to generate electrical signals that can be processed. The CMUT may comprise a top electrode that moves and a lower electrode that is stationary, where the top electrode is separated by a gap from the lower electrode. The gap may comprise some level of vacuum or the gap may be filled with, for example, air.

Certain applications may find it desirable to drive CMUTs hard enough so that they operate in collapse mode. That is, the top electrode is driven to the bottom electrode. This may permit the CMUTs to provide higher levels of acoustic power, more linearity, and wider bandwidth during operation. However, operating in collapse mode may cause the top electrode to contact the bottom electrode, resulting in an electrical short circuit of the electrodes that may cause permanent damage to the structure of the CMUT. To avoid this problem, one or more insulation layers or bumps may be sandwiched between the bottom and top electrode. An electrical reliability issue generally originates substantially from dielectric charging problems in the thin dielectric insulation layers. While various efforts have been made to overcome this problem, industrial CMUT devices to date have not been able to overcome the problems associated with operating in collapse mode due to reliability issues. Three important causes for the trapped charges are the fabrication process of the CMUT, the material quality used in the fabrication process, and strong electrical field in the gap during operation of the CMUT.

Charges can be trapped either on the surface or within a dielectric insulation layer that may be present in a conventional CMUT. Such charges can cause issues during collapse, collapse mode of operation, and membrane snapback after collapse.

While some solutions offered both from academics and industry include the use of PostCMUTs, spacers (membrane bumps), extended edge insulator thickness, and the like, these approaches merely localized the charging issue to smaller regions. The charge trapping still occurs aided sometimes by sharp edges, and, therefore, the problem still exists.

Further limitations and disadvantages of conventional and traditional approaches will become apparent to one of skill in the art, through comparison of such systems with some aspects of the present disclosure as set forth in the remainder of the present application with reference to the drawings.

### BRIEF SUMMARY

A system and/or a method for providing a reliable (i.e., defect mitigated) isolation stack in capacitive micromachined ultrasonic transducers (CMUTs) is disclosed, substantially as shown in and/or described in connection with at least one of the figures, as set forth more completely in the claims.

These and other advantages, aspects and novel features of the present disclosure, as well as details of an illustrated embodiment thereof, will be more fully understood from the following description and drawings.

### BRIEF DESCRIPTION OF SEVERAL VIEWS OF THE DRAWINGS

FIG. 1 is a block diagram of an exemplary ultrasound system, in accordance with various embodiments.

FIG. 2 is a flow chart illustrating exemplary steps that may be utilized for manufacturing a reliable (i.e., defect mitigated) isolation stack, in accordance with various embodiments.

FIGS. 3A to 3C are cross-sectional views sequentially illustrating a manufacturing method of a reliable (i.e., defect mitigated) isolation stack, in accordance with various embodiments.

FIG. 4 is a flow chart illustrating exemplary steps that may be utilized for manufacturing a capacitive micromachined ultrasonic transducer (CMUT) having a reliable (i.e., defect mitigated) isolation stack, in accordance with various embodiments.

FIGS. 5A to 5G are cross-sectional views sequentially illustrating a manufacturing method of a capacitive micromachined ultrasonic transducer (CMUT) having a reliable (i.e., defect mitigated) isolation stack, in accordance with various embodiments.

FIG. 6 illustrates an example capacitive micromachined ultrasonic transducer (CMUT) with an isolation stack on a bottom side of a top electrode, in accordance with various embodiments.

FIG. 7 illustrates an example capacitive micromachined ultrasonic transducer (CMUT) with an isolation stack on a bottom electrode, in accordance with various embodiments.

FIG. 8 illustrates an example capacitive micromachined ultrasonic transducer (CMUT) with an isolation stack on both a bottom side of the top electrode and the top side of the bottom electrode, in accordance with various embodiments.

FIG. 9 illustrates an example capacitive micromachined ultrasonic transducer (CMUT) with a rectangular isolation stack bump on a top electrode, in accordance with various embodiments.

FIG. 10 illustrates an example capacitive micromachined ultrasonic transducer (CMUT) with a triangular isolation stack bump on a top electrode, in accordance with various embodiments.

FIG. 11 illustrates an example capacitive micromachined ultrasonic transducer (CMUT) with a rounded isolation stack bump on a top electrode, in accordance with various embodiments.

FIG. 12 illustrates an example capacitive micromachined ultrasonic transducer (CMUT) with a rectangular isolation stack bump on a top electrode and an isolation stack layer on a bottom electrode, in accordance with various embodiments.

FIG. 13 illustrates an example capacitive micromachined ultrasonic transducer (CMUT) with a triangular isolation stack bump on a top electrode and an isolation stack layer on a bottom electrode, in accordance with various embodiments.

FIG. 14 illustrates an example capacitive micromachined ultrasonic transducer (CMUT) with a rounded isolation stack bump on a top electrode and an isolation stack layer on a bottom electrode, in accordance with various embodiments.

FIG. 15 illustrates an example capacitive micromachined ultrasonic transducer (CMUT) with multiple isolation stack bumps on a top electrode, in accordance with various embodiments.

FIG. 16 illustrates an example capacitive micromachined ultrasonic transducer (CMUT) with multiple isolation stack bumps on a top electrode and an isolation stack layer on a bottom electrode, in accordance with various embodiments.

FIG. 17 illustrates an example capacitive micromachined ultrasonic transducer (CMUT) with an isolation stack bump on a bottom electrode, in accordance with various embodiments.

FIG. 18 illustrates an example capacitive micromachined ultrasonic transducer (CMUT) with multiple isolation stack bumps on a bottom electrode, in accordance with various embodiments.

FIG. 19 illustrates an example capacitive micromachined ultrasonic transducer (CMUT) with an isolation stack bump on a top electrode and on a bottom electrode, in accordance with various embodiments.

FIG. 20 illustrates an example capacitive micromachined ultrasonic transducer (CMUT) with an isolation stack bump on a bottom electrode and an isolation stack layer on a top electrode, in accordance with various embodiments.

FIG. 21 illustrates an example capacitive micromachined ultrasonic transducer (CMUT) with multiple isolation stack bumps on a bottom electrode and an isolation stack layer on a top electrode, in accordance with various embodiments.

### DETAILED DESCRIPTION

Certain embodiments may be found in a capacitive micromachined ultrasonic transducers. Various embodiments of the disclosure provide a reliable (i.e., defect mitigated) isolation stack in capacitive micromachined ultrasonic transducers (CMUTs). Aspects of the present disclosure may use an isolation stack on a bottom side of the top electrode and/or on a top side of the bottom electrode. The isolation stack may prevent the top electrode from short circuiting to the bottom electrode when the top electrode is driven too much with electric signals when generating sound waves and/or receiving sound waves to generate corresponding electric signals. Accordingly, certain embodiments provide a technical effect of preventing a top electrode from short circuiting with the bottom electrode in a CMUT. Additionally, various embodiments provide a technical effect of alleviating dielectric charge buildup in the CMUT.

While a CMUT can be used for medical imaging, the CMUT may also be used for various other purposes such as, for example, ultrasound/acoustic sensing, non-destructive evaluation (NDE), ultrasound therapy (e.g., High Intensity Focused Ultrasound (HIFU)), etc., in addition to ultrasound imaging of humans or animals.

The foregoing summary, as well as the following detailed description of certain embodiments will be better understood when read in conjunction with the appended drawings. To the extent that the figures illustrate diagrams of the functional blocks of various embodiments, the functional blocks are not necessarily indicative of the division between hardware circuitry. It should be understood that the various embodiments are not limited to the arrangements and instrumentality shown in the drawings. It should also be understood that the embodiments may be combined, or that other embodiments may be utilized and that structural, logical, and electrical changes may be made without departing from the scope of the various embodiments. The following detailed description is, therefore, not to be taken in a limiting sense, and the scope of the present disclosure is defined by the appended claims and their equivalents.

As used herein, an element or step recited in the singular and preceded with the word “a” or “an” should be understood as not excluding plural of said elements or steps, unless such exclusion is explicitly stated. Furthermore, the following discussion presents various aspects of the present disclosure by providing examples thereof. Such examples are non-limiting, and thus the scope of various aspects of the present disclosure should not necessarily be limited by any particular characteristics of the provided examples. In the following discussion, the phrases “for example,” “e.g.,” and “exemplary” are non-limiting and are generally synonymous with “by way of example and not limitation,” “for example and not limitation,” and the like. Additionally, references to “an exemplary embodiment,” “various embodiments,” “certain embodiments,” “a representative embodiment,” and the like are not intended to be interpreted as excluding the existence of additional embodiments that also incorporate the recited features. Moreover, unless explicitly stated to the contrary, embodiments “comprising,” “including,” or “having” an element or a plurality of elements having a particular property may include additional elements not having that property.

Also as used herein, the term “image” broadly refers to both viewable images and data representing a viewable image. However, many embodiments generate (or are configured to generate) at least one viewable image. In addition, as used herein, the phrase “image” is used to refer to an ultrasound mode, which can be one-dimensional (1D), two-dimensional (2D), three-dimensional (3D), or four-dimensional (4D), and comprising Brightness mode (B-mode), Motion mode (M-mode), Color Motion mode (CM-mode), Color Flow mode (CF-mode), Pulsed Wave (PW) Doppler, Continuous Wave (CW) Doppler, Contrast Enhanced Ultrasound (CEUS), and/or sub-modes of B-mode and/or CF-mode such as Harmonic Imaging, Shear Wave Elasticity Imaging (SWEI), Strain Elastography, Tissue Velocity Imaging (TVI), Power Doppler Imaging (PDI), B-flow, Micro Vascular Imaging (MVI), Ultrasound-Guided Attenuation Parameter (UGAP), and the like.

Furthermore, the term processor or processing unit, as used herein, refers to any type of processing unit that can carry out the required calculations needed for the various embodiments, such as single or multi-core Central Processing Unit (CPU), Accelerated Processing Unit (APU), Graphic Processing Unit (GPU), Digital Signal Processor (DSP), Field Programmable Gate Array (FPGA), System on a Chip (SoC), Application-Specific Integrated Circuit (ASIC), or a combination thereof.

It will be understood that, although the terms first, second, etc. may be used herein to describe various elements, these elements should not be limited by these terms. These terms are only used to distinguish one element from another element. Thus, for example, a first element, a first component, a first section, or a first layer discussed below could be termed a second element, a second component, a second section, or a second layer without departing from the teachings of the present disclosure. Similarly, various spatial terms, such as “top,” “bottom,” “upper,” “lower,” “side,” and the like, may be used in distinguishing one element from another element in a relative manner. It should be understood, however, that components may be oriented in different manners, for example a CMUT may be turned sideways so that its “top” surface is facing horizontally and its “side” surface is facing vertically, without departing from the teachings of the present disclosure.

In the drawings, the thickness or size of layers, regions, and/or components may be exaggerated for clarity. Accordingly, the scope of this disclosure should not be limited by such thickness or size. Additionally, in the drawings, like reference numerals may refer to like elements throughout the discussion.

It will also be understood that when an element A is referred to as being “connected to” or “coupled to” an element B, the element A can be directly connected to the element B or indirectly connected to the element B (e.g., an intervening element C (and/or other elements) may be present between the element A and the element B).

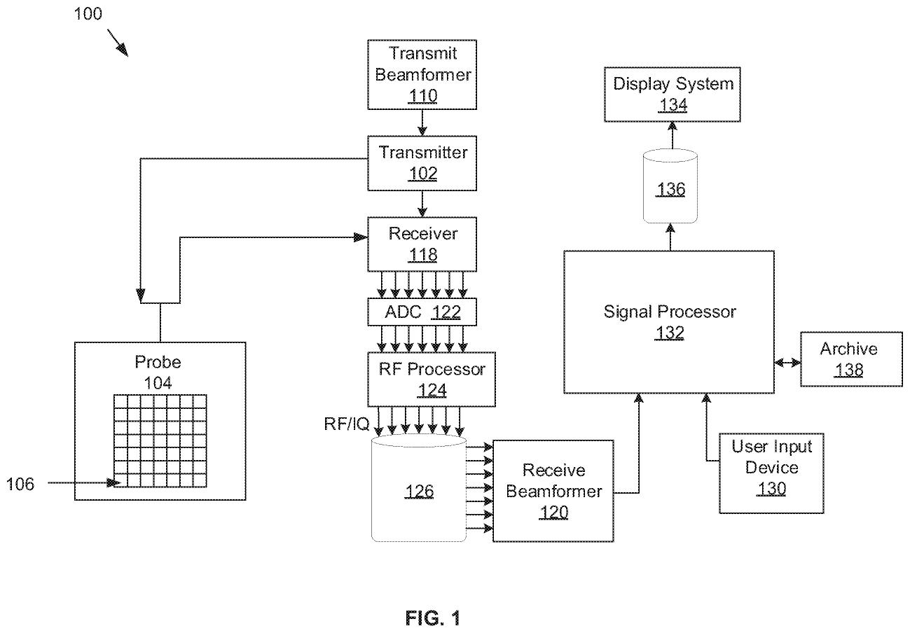

FIG. 1 is a block diagram of an exemplary ultrasound system, in accordance with various embodiments. Referring to FIG. 1, there is shown a block diagram of an exemplary ultrasound system 100. The ultrasound system 100 comprises a transmitter 102, an ultrasound probe 104, a transmit beamformer 110, a receiver 118, a receive beamformer 120, A/D converters 122, an RF processor 124, an RF/IQ buffer 126, a user input device 130, a signal processor 132, an image buffer 136, a display system 134, and an archive 138.

The transmitter 102 may comprise suitable logic, circuitry, interfaces and/or code that may be operable to drive the ultrasound probe 104. The ultrasound probe 104 may comprise, for example, a single element CMUT, a 1D array of CMUTs, 2D array of CMUTs, an annular (ring) array of CMUTs, or the like. Accordingly, the ultrasound probe 104 may comprise a group of transducer elements 106 that may be, for example, CMUTs. In certain embodiments, the ultrasound probe 104 may be operable to acquire ultrasound image data covering, for example, at least a substantial portion of an anatomy, such as the heart, a blood vessel, or any suitable anatomical structure. Each of the transducer elements 106 may be referred to as a channel.

The transmit beamformer 110 may comprise suitable logic, circuitry, interfaces and/or code that may be operable to control the transmitter 102 that drives the group of transducer elements 106 to emit ultrasonic transmit signals into a region of interest (e.g., human, animal, underground cavity, physical structure and the like). The transmitted ultrasonic signals may be back-scattered from structures in the object of interest, like blood cells or tissue, to produce echoes. The echoes can then be received by the transducer elements 106.

The group of transducer elements 106 in the ultrasound probe 104 may be operable to convert the received echoes into analog signals and communicated to a receiver 118. The receiver 118 may comprise suitable logic, circuitry, interfaces and/or code that may be operable to receive the signals from the ultrasound probe 104. The analog signals may be communicated to one or more of the plurality of A/D converters 122.

Accordingly, the ultrasound system 100 may multiplex such that ultrasonic transmit signals are transmitted during certain time periods and echoes of those ultrasonic signals are received during other time periods. Although not shown explicitly, various embodiments of the disclosure may allow simultaneous transmission of ultrasonic signals and reception of echoes from those signals. In such cases, the probe may comprise transmit transducer elements and receive transducer elements.

The plurality of A/D converters 122 may comprise suitable logic, circuitry, interfaces and/or code that may be operable to convert the analog signals from the receiver 118 to corresponding digital signals. The plurality of A/D converters 122 are disposed between the receiver 118 and the RF processor 124. Notwithstanding, the disclosure is not limited in this regard. Accordingly, in some embodiments, the plurality of A/D converters 122 may be integrated within the receiver 118.

The RF processor 124 may comprise suitable logic, circuitry, interfaces and/or code that may be operable to demodulate the digital signals output by the plurality of A/D converters 122. In accordance with an embodiment, the RF processor 124 may comprise a complex demodulator (not shown) that is operable to demodulate the digital signals to form I/Q data pairs that are representative of the corresponding echo signals. The RF data, which may be, for example, I/Q signal data, real valued RF data, etc., may then be communicated to an RF/IQ buffer 126. The RF/IQ buffer 126 may comprise suitable logic, circuitry, interfaces and/or code that may be operable to provide temporary storage of the RF or I/Q signal data, which is generated by the RF processor 124.

Accordingly, various embodiments may have, for example, the RF processor 124 process real valued RF data, or any other equivalent representation of the data, with an appropriate RF buffer 126.

The receive beamformer 120 may comprise suitable logic, circuitry, interfaces and/or code that may be operable to perform digital beamforming processing to sum, for example, delayed, phase shifted, and/or weighted channel signals received from the RF processor 124 via the RF/IQ buffer 126 and output a beam summed signal. The delayed, phase shifted, and/or weighted channel data may be summed to form a scan line output from the receive beamformer 120, where the scan line may be, for example, complex valued or non-complex valued. The specific delay for a channel may be provided, for example, by the RF processor 124 or any other processor configured to perform the task. The delayed, phase shifted, and/or weighted channel data may be referred to as delay aligned channel data.

The resulting processed information may be the beam summed signal that is output from the receive beamformer 120 and communicated to the signal processor 132. In accordance with some embodiments, the receiver 118, the plurality of A/D converters 122, the RF processor 124, and the beamformer 120 may be integrated into a single beamformer, which may be digital. In various embodiments, the ultrasound system 100 may comprise a plurality of receive beamformers 120.

The user input device 130 may be utilized to input patient data, scan parameters, settings, select protocols and/or templates, and the like. In an exemplary embodiment, the user input device 130 may be operable to configure, manage, and/or control operation of one or more components and/or modules in the ultrasound system 100. In this regard, the user input device 130 may be operable to configure, manage and/or control operation of the transmitter 102, the ultrasound probe 104, the transmit beamformer 110, the receiver 118, the receive beamformer 120, the RF processor 124, the RF/IQ buffer 126, the user input device 130, the signal processor 132, the image buffer 136, the display system 134, and/or the archive 138. The user input device 130 may include switch(es), button(s), rotary encoder(s), a touchscreen, motion tracking, voice recognition, a mouse device, keyboard, camera, and/or any other device capable of receiving a user directive. In certain embodiments, one or more of the user input devices 130 may be integrated into other components, such as the display system 134 or the ultrasound probe 104, for example. As an example, user input device 130 may comprise a touchscreen display.

The signal processor 132 may comprise suitable logic, circuitry, interfaces and/or code that may be operable to process ultrasound scan data (i.e., summed IQ signal) for generating ultrasound images for presentation on a display system 134. The signal processor 132 is operable to perform one or more processing operations according to a plurality of selectable ultrasound modalities on the acquired ultrasound scan data. In an exemplary embodiment, the signal processor 132 may be operable to perform display processing and/or control processing, among other things. Acquired ultrasound scan data may be processed in real-time during a scanning session as the echo signals are received. Additionally or alternatively, the ultrasound scan data may be stored temporarily in the RF/IQ buffer 126 during a scanning session and processed in a live or off-line operation. In various embodiments, the processed image data can be presented at the display system 134 and/or stored at the archive 138. The archive 138 may be a local archive, a Picture Archiving and Communication System (PACS), or any suitable device for storing images and related information.

The signal processor 132 may comprise one or more central processing units, microprocessors, microcontrollers, and/or the like. The signal processor 132 may be an integrated component, or may be distributed across various locations, for example. In an exemplary embodiment, the signal processor 132 may be capable of receiving input information from the user input device 130 and/or the archive 138, generating an output displayable by the display system 134, and manipulating the output in response to input information from the user input device 130, among other things. The signal processor 132 may be capable of executing any of the method(s) and/or set(s) of instructions discussed herein in accordance with the various embodiments, for example.

The ultrasound system 100 may be operable to continuously acquire ultrasound scan data at a frame rate that is suitable for the imaging situation in question. Typical frame rates may range from 20-120 but may be lower or higher. The acquired ultrasound scan data may be displayed on the display system 134 at a display-rate that can be the same as the frame rate, or slower or faster. An image buffer 136 is included for storing processed frames of acquired ultrasound scan data that are not scheduled to be displayed immediately. Preferably, the image buffer 136 is of sufficient capacity to store at least several minutes worth of frames of ultrasound scan data. The frames of ultrasound scan data are stored in a manner to facilitate retrieval thereof according to its order or time of acquisition. The image buffer 136 may be embodied as any known data storage medium.

The display system 134 may be any device capable of communicating visual information to a user. For example, a display system 134 may include a liquid crystal display, a light emitting diode display, and/or any suitable display or displays. The display system 134 can be operable to present ultrasound images and/or any suitable information.

The archive 138 may be one or more computer-readable memories integrated with the ultrasound system 100 and/or communicatively coupled (e.g., over a network) to the ultrasound system 100, such as a Picture Archiving and Communication System (PACS), a server, a hard disk, floppy disk, CD, CD-ROM, DVD, compact storage, flash memory, random access memory, read-only memory, electrically erasable and programmable read-only memory and/or any suitable memory. The archive 138 may include databases, libraries, sets of information, or other storage accessed by and/or incorporated with the signal processor 132, for example. The archive 138 may be able to store data temporarily or permanently, for example. The archive 138 may be capable of storing medical image data, data generated by the signal processor 132, and/or instructions readable by the signal processor 132, among other things.

Components of the ultrasound system 100 may be implemented in software, hardware, firmware, and/or the like. The various components of the ultrasound system 100 may be communicatively linked. Components of the ultrasound system 100 may be implemented separately and/or integrated in various forms. For example, the display system 134 and the user input device 130 may be integrated as a touchscreen display. Additionally, while the ultrasound system 100 was described to comprise a receive beamformer 120, an RF processor 124, and a signal processor 132, various embodiments of the disclosure may use various number of processors. For example, various devices that execute code may be referred to generally as processors. Various embodiments may refer to each of these devices, including each of the RF processor 124 and the signal processor 132, as a processor. Furthermore, there may be other processors to additionally perform the tasks described as being performed by these devices, including the receive beamformer 120, the RF processor 124, and the signal processor 132, and all of these processors may be referred to as a “processor” for ease of description.

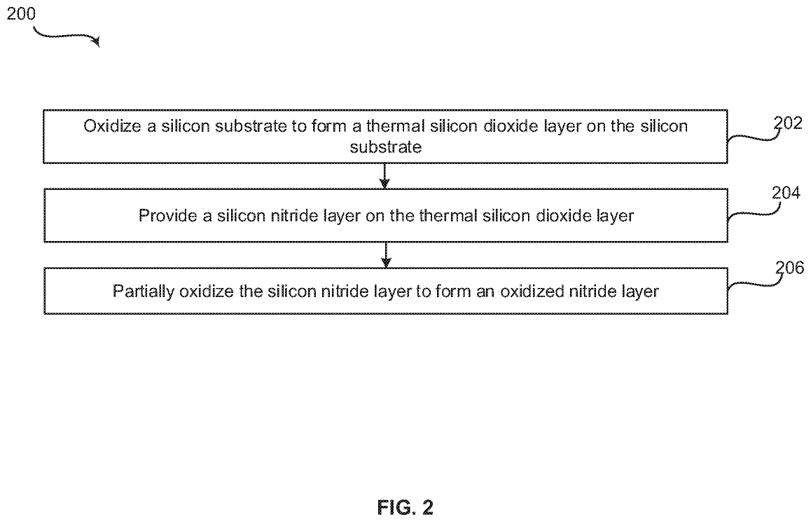

FIG. 2 is a flow chart 200 illustrating exemplary steps 202-206 that may be utilized for manufacturing a reliable (i.e., defect mitigated) isolation stack, in accordance with various embodiments. Referring to FIG. 2, there is shown a flow chart 200 comprising exemplary steps 202 through 206. Certain embodiments may omit one or more of the steps, and/or perform the steps in a different order than the order listed, and/or combine certain of the steps discussed below. For example, some steps may not be performed in certain embodiments. As a further example, certain steps may be performed in a different temporal order, including simultaneously, than listed below.

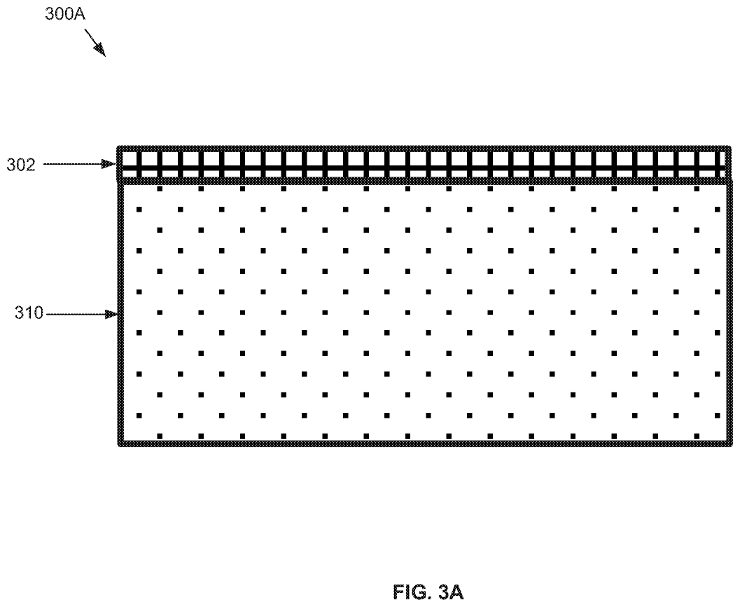

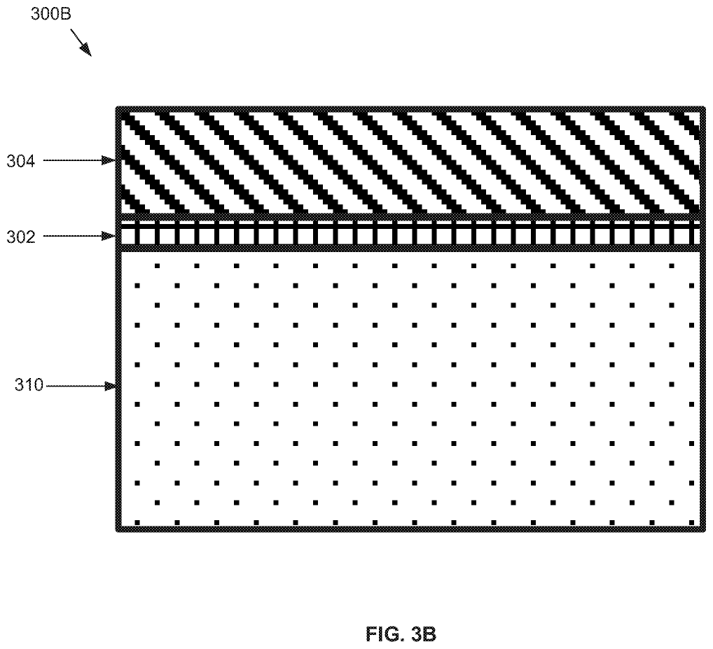

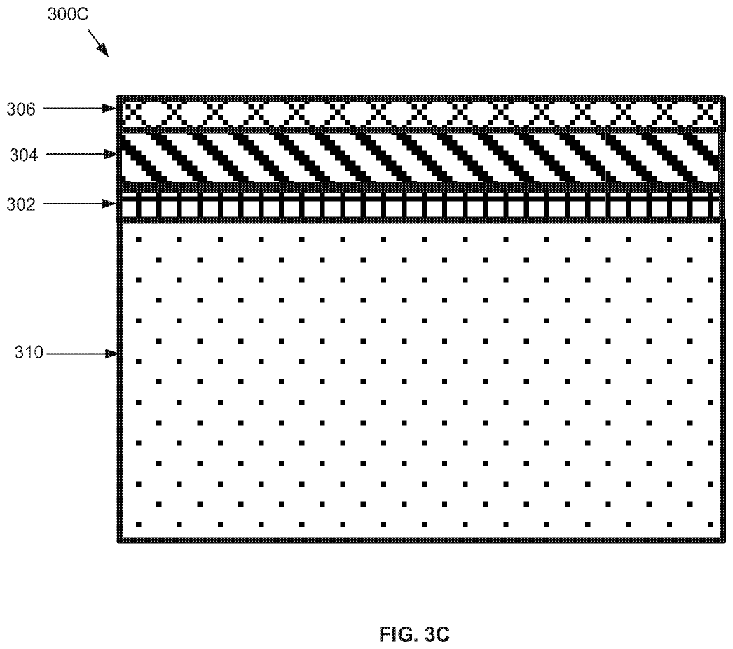

FIGS. 3A to 3C are cross-sectional views sequentially illustrating a manufacturing method of a reliable (i.e., defect mitigated) isolation stack, in accordance with various embodiments.

At step 202, with reference to FIGS. 2 and 3A, a silicon substrate 310 is oxidized to form a silicon dioxide layer 302 on the silicon substrate 310. For example, the silicon substrate 310 may be placed in a furnace to perform thermal oxidation. The thermal silicon dioxide layer 302 formed by the oxidation may have a thickness (i.e., vertical height from the silicon substrate 310) of at least 10 nanometers. In various embodiments, the thickness of the thermal silicon dioxide layer 302 is approximately 25 nanometers (i.e., 10-50 nanometers). The thermal silicon dioxide layer 302 may also be referred to as a pad oxide layer 302.

At step 204, with reference to FIGS. 2 and 3B, a silicon nitride layer 304 is provided on the thermal silicon dioxide layer 302. For example, the silicon nitride layer 304 may be formed by chemical vapor deposition (CVD) or using any suitable technique. In various embodiments, the silicon nitride layer may have a thickness of 50-500 nanometers based on performance or defined figure-of-merit requirements of a particular CMUT device.

At step 206, with reference to FIGS. 2 and 3C, the silicon nitride layer 304 is partially oxidized to form an oxidized nitride layer 306. For example, the partial oxidation of the silicon nitride layer 304 may be performed via conventional pyrogenic processes, such as wet or dry thermal oxidation, among other things. In various embodiments, the silicon nitride layer 304 may be oxidized multiple times (e.g., a first field oxidation and a second field oxidation) to form the oxidized nitride layer 306. In a representative embodiment, the oxidized nitride layer is at least 4 nanometers thick. For example, the oxidized nitride layer 306 may have a thickness of 4-10 nanometers based on performance or defined figure-of-merit requirements of a particular CMUT device. The partial oxidation at step 206 is performed on a partial thin top region of the silicon nitride 304 itself, without forming a separate layer of silicon dioxide on the silicon nitride layer 304. The silicon nitride layer 304 and the oxidized nitride layer 306 may collectively be referred to as a partially oxidized silicon nitride.

The resulting stack, from bottom to top, of the pad oxide layer 302, the silicon nitride layer 304, and the oxidized nitride layer 306 is referred to herein as an isolation stack. In various embodiments, a self-assembled monolayer and/or monolayers of silicon carbide may be applied on the isolation stack for added lubrication during contact due to collapse operation, which can mitigate extrinsic tribo-effect or surface roughness-related charging issues.

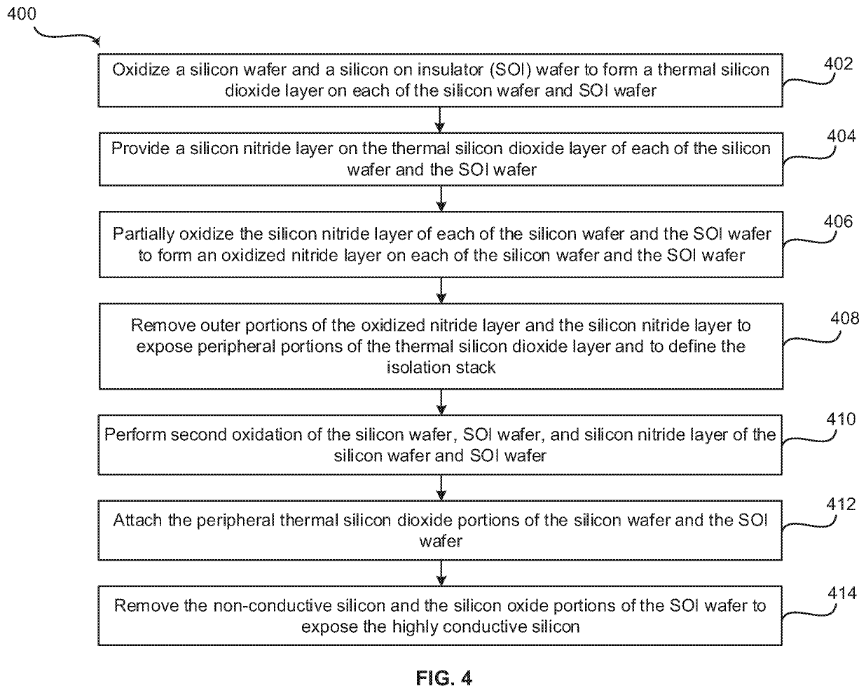

FIG. 4 is a flow chart 400 illustrating exemplary steps 402-414 that may be utilized for manufacturing a capacitive micromachined ultrasonic transducer (CMUT) having a reliable (i.e., defect mitigated) isolation stack 302-306, in accordance with various embodiments. Referring to FIG. 4, there is shown a flow chart 400 comprising exemplary steps 402 through 414. Certain embodiments may omit one or more of the steps, and/or perform the steps in a different order than the order listed, and/or combine certain of the steps discussed below. For example, some steps may not be performed in certain embodiments. As a further example, certain steps may be performed in a different temporal order, including simultaneously, than listed below.

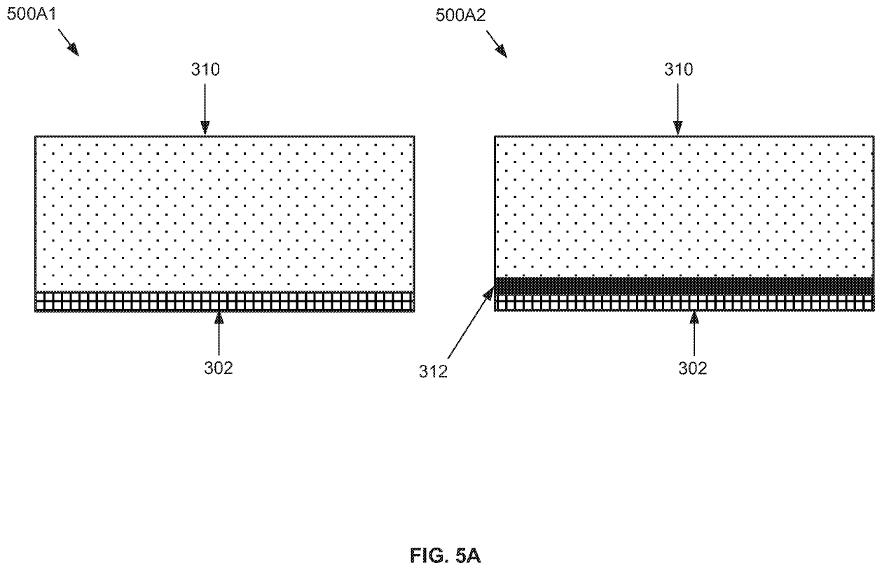

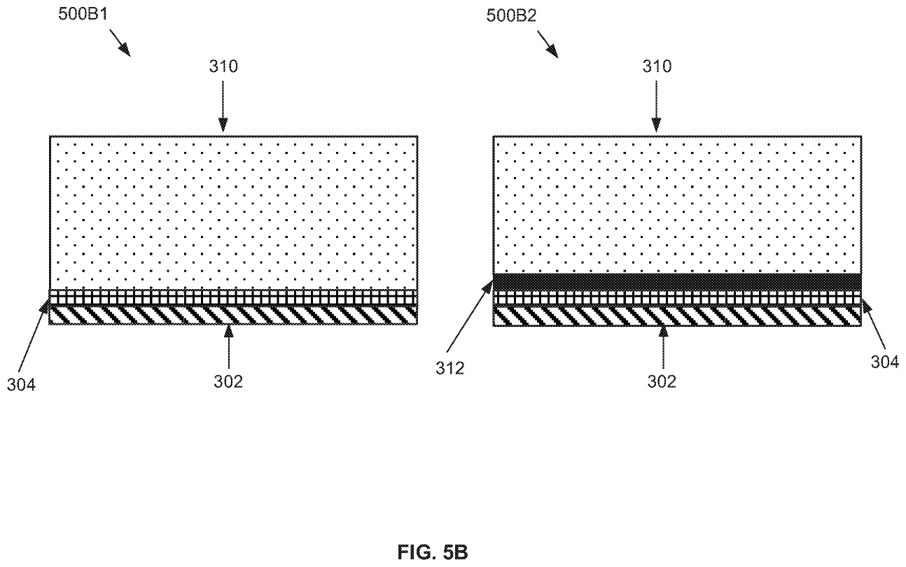

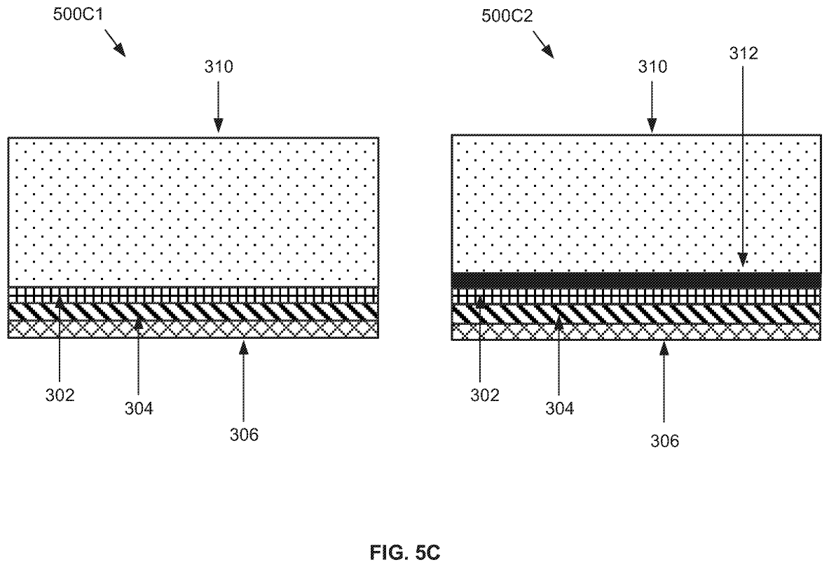

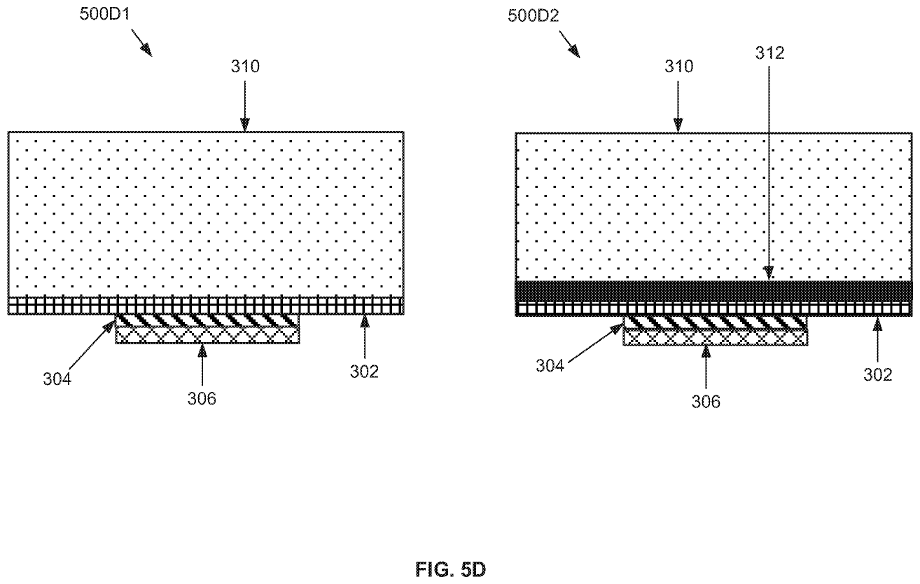

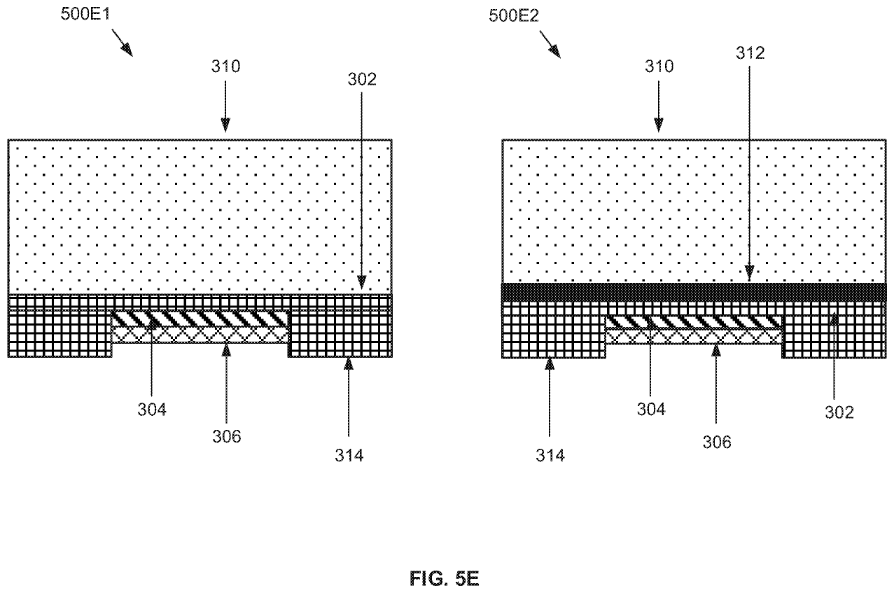

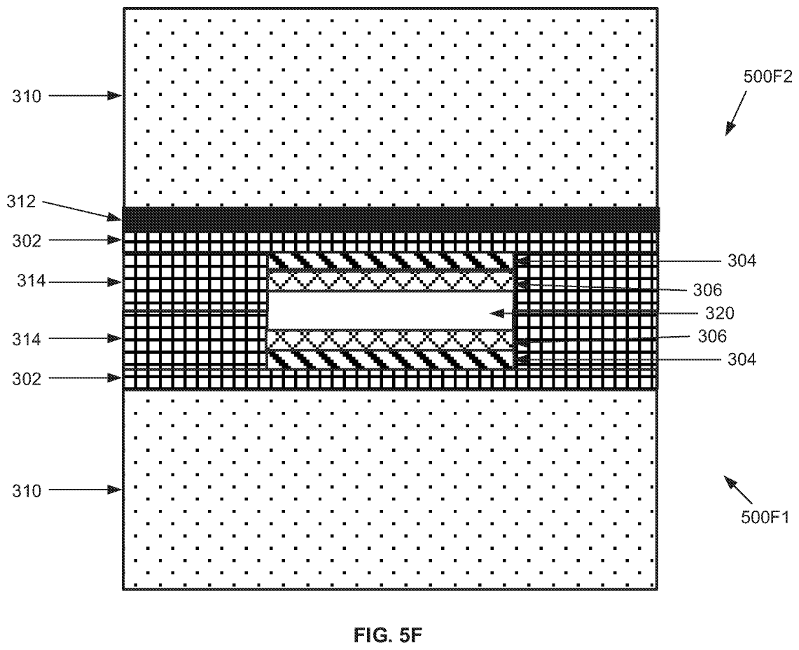

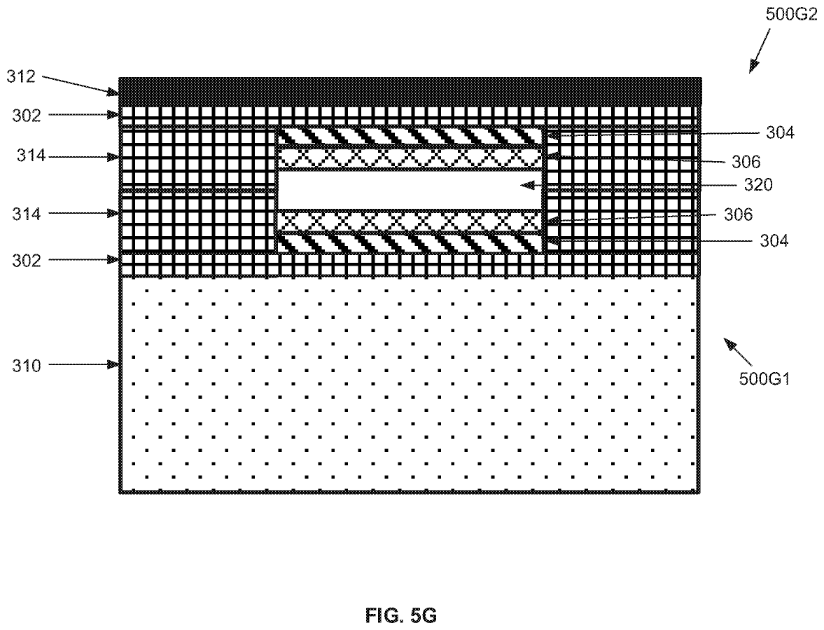

FIGS. 5A to 5G are cross-sectional views sequentially illustrating a manufacturing method of a capacitive micromachined ultrasonic transducer (CMUT) having a reliable (i.e., defect mitigated) isolation stack 302-306, in accordance with various embodiments.

At step 402, with reference to FIGS. 4 and 5A, a silicon wafer substrate 310 and a silicon on insulator (SOI) 310, 312 are each oxidized to form a silicon dioxide layer 302 on each of the silicon wafer substrate 310 and the silicon on insulator (SOI) wafer 310, 312. For example, a first assembly 500A1 may correspond to a bottom portion of a CMUT device and a second assembly 500A2 may correspond with a top portion of the CMUT device. The first and second assemblies 500A1, 500A2 may be processed in a same way to form the CMUT device. The SOI wafer 310, 312 may comprise, from top to bottom, silicon 310, silicon oxide (not shown), and a highly conductive silicon 312. The silicon wafer substrate 310 and SOI wafer 310, 312 may be placed in a furnace to perform thermal oxidation. The thermal silicon dioxide layer 302 formed on the silicon wafer substrate 310 and the highly conductive silicon 312 of the SOI wafer 310, 312 by the oxidation may have a thickness of at least 10 nanometers. In various embodiments, the thickness of the thermal silicon dioxide layer 302 on each of the silicon wafer substrate 310 and the SOI wafer 310, 312 is approximately 25 nanometers (i.e., 10-50 nanometers).

At step 404, with reference to FIGS. 4 and 5B, a silicon nitride layer 304 is provided on the thermal silicon dioxide layer 302 of each of the silicon wafer substrate 310 and the SOI wafer 310, 312. For example, the silicon nitride layer 304 may be formed by chemical vapor deposition (CVD) or using any suitable technique. In various embodiments, the silicon nitride layer may have a thickness of 50-500 nanometers based on performance or defined figure-of-merit requirements of a particular CMUT device.

At step 406, with reference to FIGS. 4 and 5C, the silicon nitride layer 304 of each of the silicon wafer 310 and the SOI wafer 310, 312 is partially oxidized to form an oxidized nitride layer 306 on each of the silicon wafer 310 and the SOI wafer 310, 312. For example, the partial oxidation of the silicon nitride layer 304 may be performed via conventional pyrogenic processes, such as wet or dry thermal oxidation, among other things. The partial oxidation at step 406 is performed on a partial thin top region of the silicon nitride 304 itself, without forming a separate layer of silicon dioxide on the silicon nitride layer 304 of each of the silicon wafer 310 and the SOI wafer 310, 312.

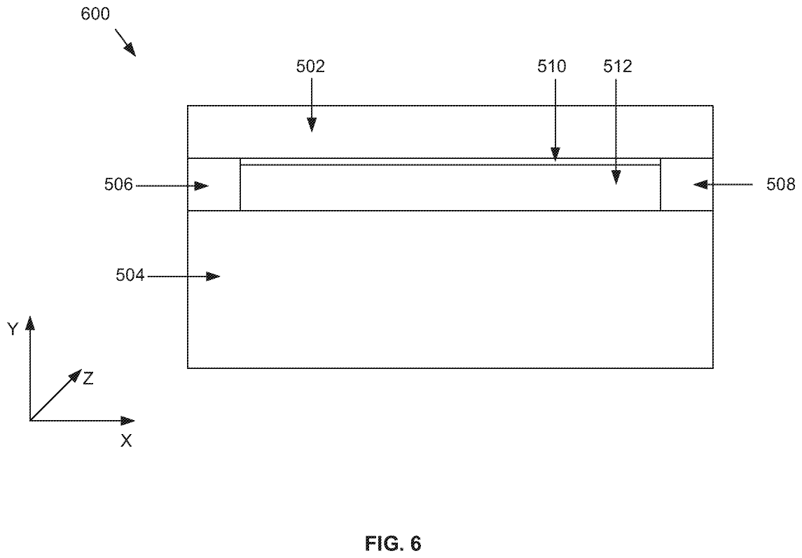

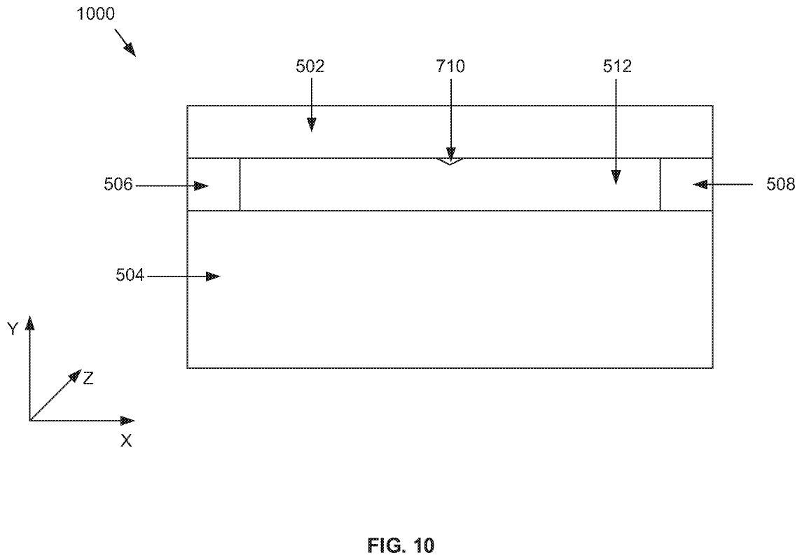

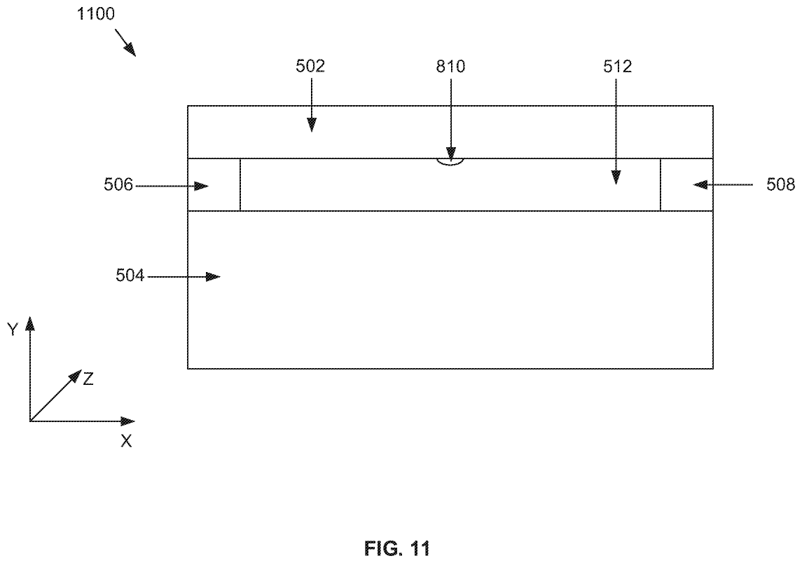

At step 408, with reference to FIGS. 4 and 5D, outer portions of the oxidized nitride layer 306 and the silicon nitride layer 304 may be removed to expose peripheral portions of the thermal silicon dioxide layer 302 and to define the isolation stack 302, 304, 306. For example, as discussed in more detail below with reference to FIGS. 6-22, the isolation stack 302, 304, 306 may be provided as a layer or bump of various shaped and sizes. In an exemplary embodiment, the removal of the outer portions of the oxidized nitride layer 306 and the silicon nitride layer 304 may be performed by etching or any suitable technique.

At step 410, with reference to FIGS. 4 and 5E, the silicon wafer 310, SOI wafer 310, 312, and the silicon nitride layer 304 of each of the silicon wafer 310 and the SOI wafer 310, 312 is partially oxidized a second time. For example, the further oxidation of the silicon wafer 310 and SOI wafer 310, 312 may form the sidewalls (also referred to as standoffs) 314 of the CMUT device. The sidewalls 314 on the first assembly 500E1 and the second assembly 500E2 define a gap in the completed CMUT device, where the gap is divided equally between the first assembly 500E1 and the second assembly 500E2. Although the gap is divided equally in the exemplary embodiment of FIG. 5E, in various embodiments, the gap may be divided according to any suitable ratio. As another example, the second partial oxidation of the silicon nitride layer 304 helps ensure that the oxidized nitride layer 306 attains a thickness of at least 4 nanometers. In various embodiments, the oxidized nitride layer 306 may have a thickness of 4-10 nanometers based on performance or defined figure-of-merit requirements of a particular CMUT device.

At step 412, with reference to FIGS. 4 and 5F, the peripheral thermal silicon dioxide portions 314 of the silicon wafer 310 and the SOI wafer 310, 312 are attached. For example, the peripheral thermal silicon dioxide portions 314 form the sidewalls of the first 500F1 and second 500F2 assemblies. The thermal silicon dioxide portions 314 of the first assembly 500F1 may be attached to the thermal silicon dioxide portion 314 of the second assembly 500F2 by a fusion bonding process or any suitable process. The attached first 500F1 and second 500F2 assemblies provide a gap 320 between the isolation stacks 302, 304, 306 on each of a top electrode formed by the highly conductive silicon 312 of the SOI wafer 310, 312 and a bottom electrode formed by the silicon wafer 310.

At step 414, with reference to FIGS. 4 and 5G, the non-conductive silicon 310 and the silicon oxide portions of the SOI wafer 310, 312 are removed to expose the highly conductive silicon 312. For example, the silicon 310 and silicon oxide portions of the SOI wafer 310, 312 may be removed by grinding or any suitable process. The resulting device is a CMUT device having the highly conductive silicon 312 as a top electrode, the silicon wafer 310 as the bottom electrode, sidewalls formed from the thermal silicon dioxide portions 314, isolation stacks 302, 304, 306 formed on the top 312 and bottom 310 electrodes, and a gap 320 between the isolation stacks 302, 304, 306. In various embodiments, a self-assembled monolayer and/or monolayers of silicon carbide may be applied on the isolation stacks 302, 304, 306 for added lubrication during contact due to collapse operation, which can mitigate extrinsic tribo-effect or surface roughness-related charging issues.

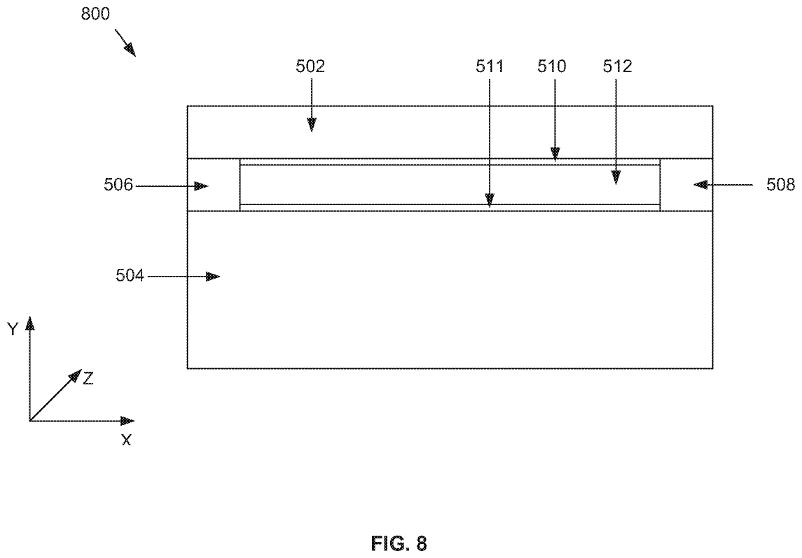

The exemplary CMUT device 500G1, 500G2 of FIG. 5G shares various characteristics with the exemplary CMUT device 800 of FIG. 8 as described below. In various embodiments, the method of manufacturing the CMUT device 500G1, 500G2 having the isolation stacks 302, 304, 306 may be modified to provide the isolation stacks 302, 304, 306 as one or more bumps on the top electrode 312 and/or bottom electrode 310, instead of as a layer on the top electrode 312 and a layer on the bottom electrode 310. The isolation stack bump(s) may be of various shapes and/or sizes. Moreover, the method of manufacturing the CMUT device having the isolation stacks 302, 304, 306 may be modified to provide the isolation stack 302, 304, 306 as a layer on only one of the top electrode 312 or the bottom electrode 310, instead of as a layer on both the top electrode 312 and the bottom electrode 310. Additionally, the method of manufacturing the CMUT device having the isolation stacks 302, 304, 306 may be modified to provide the isolation stack 302, 304, 306 as any suitable combination of bumps and/or layers on the top 312 and/or bottom 310 electrodes. Various exemplary configurations of the isolation stack(s) of the CMUT device are described below with references to FIGS. 6-22.

FIGS. 6-22 illustrate cross-sectional views of various configurations for capacitive micromachined ultrasonic transducers 600, 700, 800, 900-2200 that may be used with one or more isolation stacks 510, 511, 610, 611, 710, 810 (i.e., corresponding with the isolation stack 302, 304, 306 of FIGS. 3C and 5C-G). While some configurations are shown, it should be understood that the disclosure allows for various other configurations that may also be used for CMUTs.

FIGS. 6-8 illustrate various examples of capacitive micromachined ultrasonic transducers 600, 700, 800 using an isolation stack 510, 511 on the top electrode 502 and/or the bottom electrode 504. For example, FIG. 6 illustrates a cross-sectional view of a CMUT 600 with a top electrode 502, a bottom electrode 504, sidewalls 506 and 508, a top layer 510 made of an isolation stack (i.e., the isolation stack 302, 304, 306 of FIGS. 3C and 5C-G), and a gap 512 that may be filled with gas, such as, for example, air, or may comprise some level of vacuum. Accordingly, the sidewalls 506, 508 may define the effective gap (g_{eff}) comprising the top isolation stack layer 510 and the gap 512.

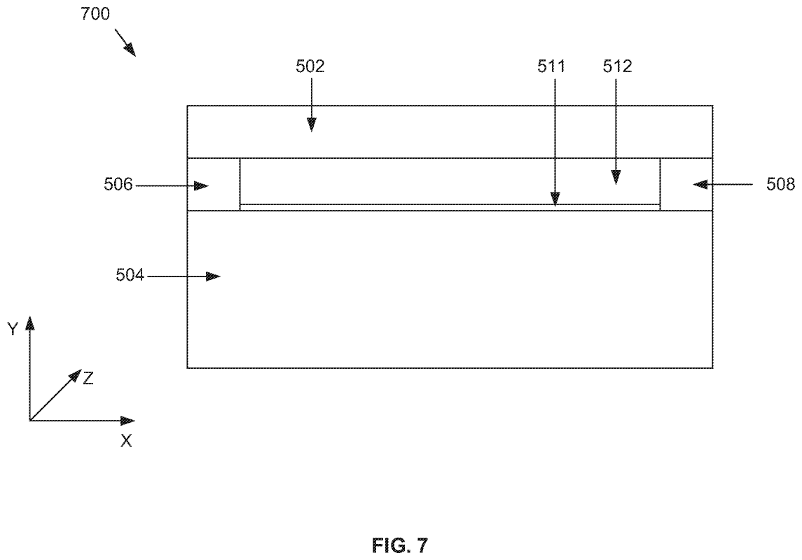

FIG. 7 is similar to FIG. 6, except that there is a bottom layer 511 made of an isolation stack (i.e., the isolation stack 302, 304, 306 of FIGS. 3C and 5C-G) rather than the top layer 510. Accordingly, the sidewalls 506, 508 may define the effective gap (g_{eff}) comprising the bottom layer 511 and the gap 512.

While FIGS. 6 and 7, as well as other figures, show the top layer 510 and the bottom layer 511 as extending from the sidewall 506 to the sidewall 508, various embodiments of the disclosure may have the top layer 510 and/or the bottom layer 511 extending under the sidewalls 506 and/or 508.

While FIGS. 6 and 7, as well as other figures, show the top layer 510 and the bottom layer 511 as extending from the sidewall 506 to the sidewall 508, the top layer 502 and/or the bottom layer 504 may extend only a portion of the width between the sidewalls 506 and 508.

FIG. 8 combines FIGS. 6 and 7, so that there is the top layer 510 and the bottom layer 511. Accordingly, the sidewalls 506, 508 may define the effective gap (g_{eff}) comprising the top 510 and bottom 511 layers and the gap 512.

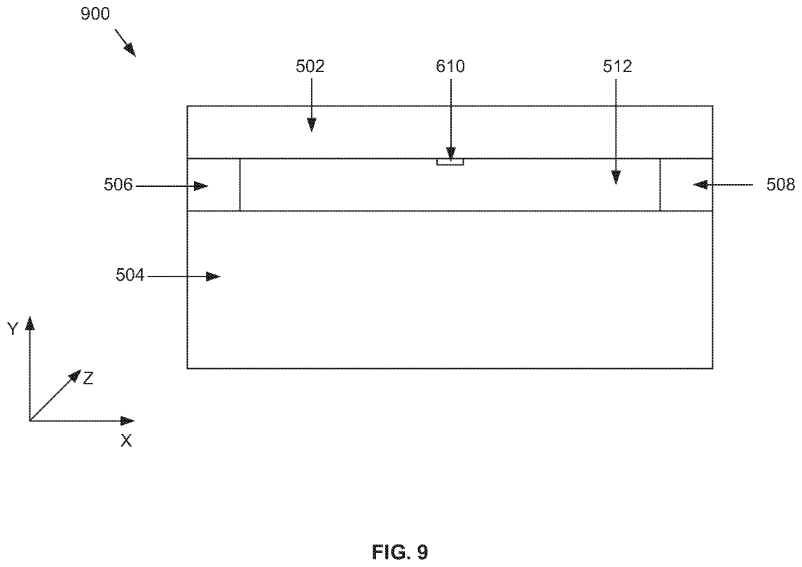

The top layer 510 and/or the bottom layer 511 may extend substantially over an area in the X-Z plane for the CMUT 800, or for a partial area in the X-Z plane. When the layer 510, 511 forms a partial area in the X-Z plane, it may be referred to as a bump. A bump may be different sizes in terms of area. FIGS. 9-22 show bumps 610, 611, 710, 810 that are a fraction of a length of a CMUT 900-2200. However, various embodiments of the disclosure need not be so limited.

FIGS. 9-11 illustrate various examples of capacitive micromachined ultrasonic transducers 900-1100 using a bump 610, 710, 810 made of an isolation stack (i.e., the isolation stack 302, 304, 306 of FIGS. 3C and 5C-G). Each of the bumps 610, 710, 810 may be substantially centered, for example, across a width of the top electrode 502 (e.g., along a direction X of the CMUT). However, various embodiments of the disclosure may put the bump 610, 710, 810 at a different location that is not centered. A bump 610, 710, 810 may be various shapes such as, for example, the rectangular bump 610, a triangular bump 710, and a rounded bump 810. Accordingly, the sidewalls 506, 508 may define the effective gap (g_{eff}) comprising the bump 610, 710, or 810 and the gap 512.

Additionally, as FIGS. 9-11 show respective cross-sectional views of the CMUT 900-1100, each bump 610, 710, 810 may extend into the Z direction of a CMUT (into and out of the paper) or there may be multiple bumps in the Z direction. Additionally, as a cross-sectional view of a bump 610, 710, 810 is shown, a bump 610, 710, 810 may comprise any shape where a cross-section of the bump 610, 710, 810 is rectangular, triangular, rounded, or any suitable shape. Where there is a single bump 610, 710, 810 in the X direction, as shown, for example, in FIGS. 9-11, the bump 610, 710, 810 may be substantially centered along the X axis of the CMUT 900-1100. However, various embodiments may place the bump 610, 710, 810 so that it is not substantially centered along the X axis of the CMUT 900-1100.

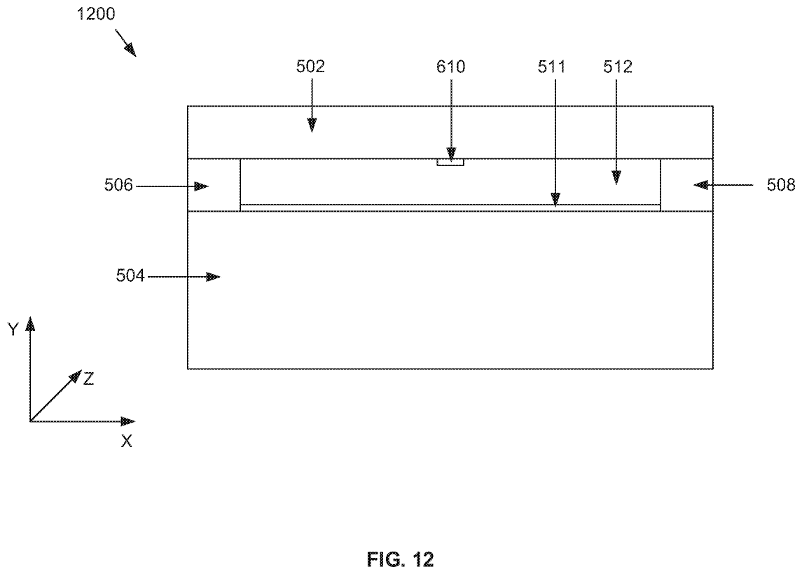

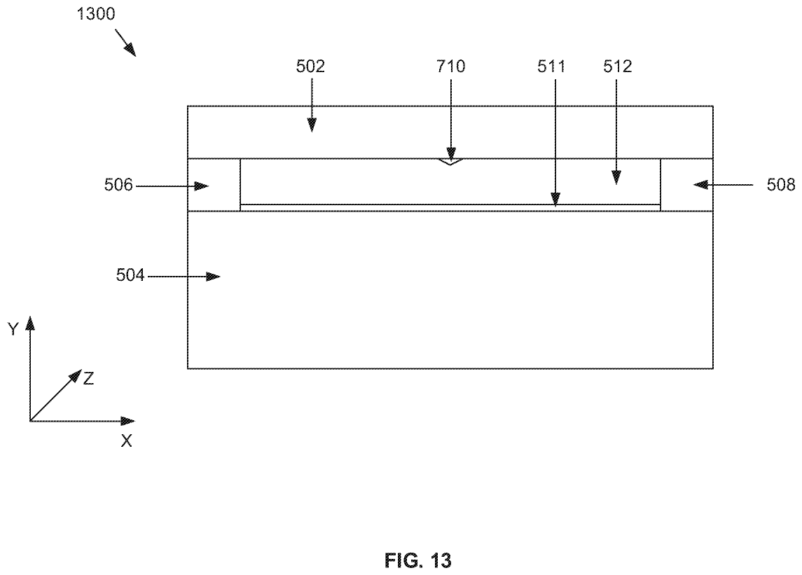

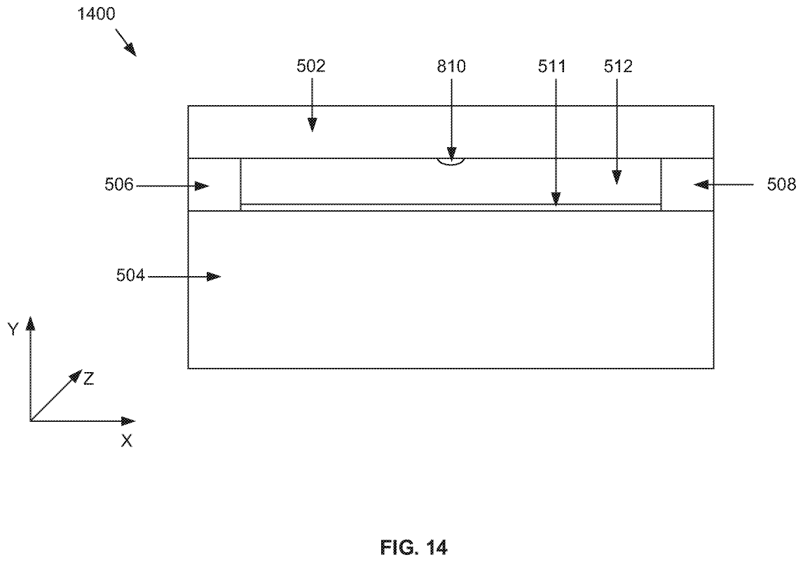

FIGS. 12-14 illustrate various examples of capacitive micromachined ultrasonic transducers with a bump 610, 710, or 810 on the top electrode 502 and an isolation stack 511 on the bottom electrode 504. For example, FIG. 12 shows a cross-section view of a CMUT 1200 comprising a rectangular bump 610 and a bottom layer 511. FIG. 13 shows a cross-section view of a CMUT 1300 comprising a triangular bump 710 and a bottom layer 511. FIG. 14 shows a cross-section view of a CMUT 1400 comprising a rounded bump 810 and a bottom layer 511. Accordingly, the sidewalls 506, 508 may define the effective gap (g_{eff}) comprising the bump 610, 710, or 810, the bottom isolation stack layer 511, and the gap 512.

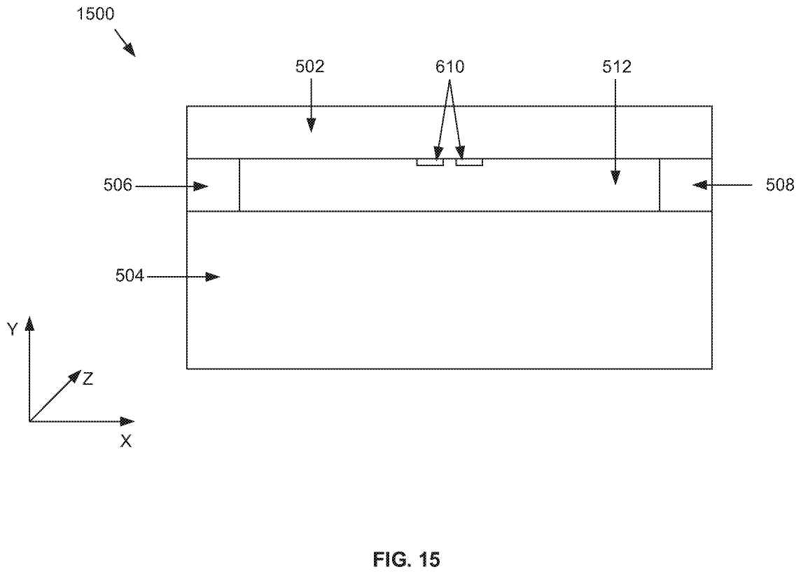

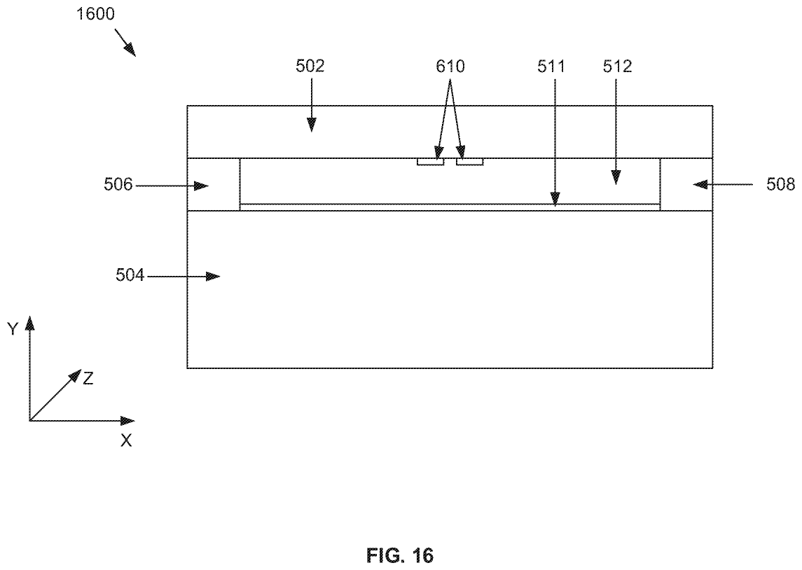

FIGS. 15 and 16 illustrate examples of capacitive micromachined ultrasonic transducers (CMUT) 1500, 1600 with multiple isolation stack bumps 610 on a top electrode 502. While two bumps 610 are shown, there may be more than two bumps 610. Additionally, while the bumps 610 are shown to be substantially centered across a width of the top electrode 502 (e.g., along the direction X), various embodiments of the disclosure may place the bumps 610 at different positions. FIG. 15 illustrates a configuration similar to that shown for CMUT 900 in FIG. 9 except that there are two bumps 610. Accordingly, the sidewalls 506, 508 may define the effective gap (g_{eff}) comprising the bumps 610 and the gap 512.

FIG. 16 illustrates a configuration similar to that shown for CMUT 1200 in FIG. 12 except that there are two bumps 610. Accordingly, the sidewalls 506, 508 may define the effective gap (g_{eff}) comprising the bumps 610, the bottom isolation stack layer 511, and the gap 512.

Where there are multiple bumps 610, 611, 710, 810 in the X direction, as shown, for example, in FIGS. 15-16, 18, and 21-22, the bumps 610, 611, 710, 810 as a unit may be substantially centered along the X axis of the CMUT 600, 700, 800, 900-2200. However, various embodiments may place the bumps 610, 611, 710, 810 so that they are not substantially centered as a unit along the X axis of the CMUT 600, 700, 800, 900-2200. Accordingly, any of the individual bumps 610, 611, 710, 810 may be placed in different positions along a dimension of the CMUT 600, 700, 800, 900-2200.

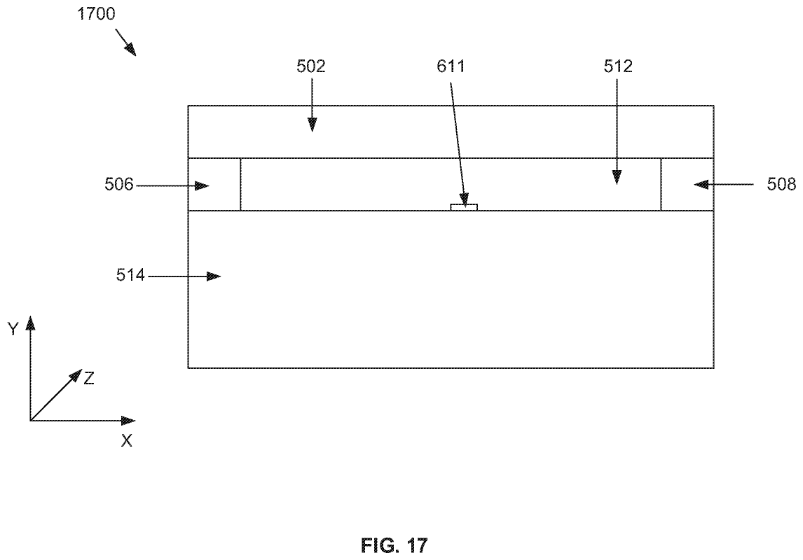

FIG. 17 illustrates an example capacitive micromachined ultrasonic transducer (CMUT) 1700 similar to the CMUT 900 of FIG. 9 except that an isolation stack bump 611 on the bottom electrode 504 is shown rather than isolation stack bump 610 on the top electrode 502. Accordingly, the sidewalls 506, 508 may define the effective gap (g_{eff}) comprising the bump 611 and the gap 512.

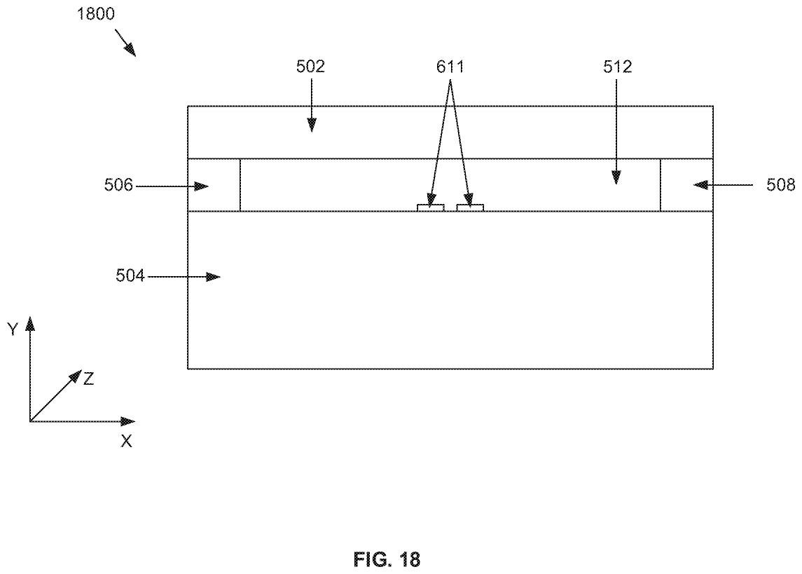

FIG. 18 illustrates an example capacitive micromachined ultrasonic transducer (CMUT) 1800 similar to the CMUT 1500 of FIG. 15 except that isolation stack bumps 611 on the bottom electrode 504 are shown rather than isolation stack bumps 610 on the top electrode 502. Accordingly, the sidewalls 506, 508 may define the effective gap (g_{eff}) comprising the bumps 611 and the gap 512.

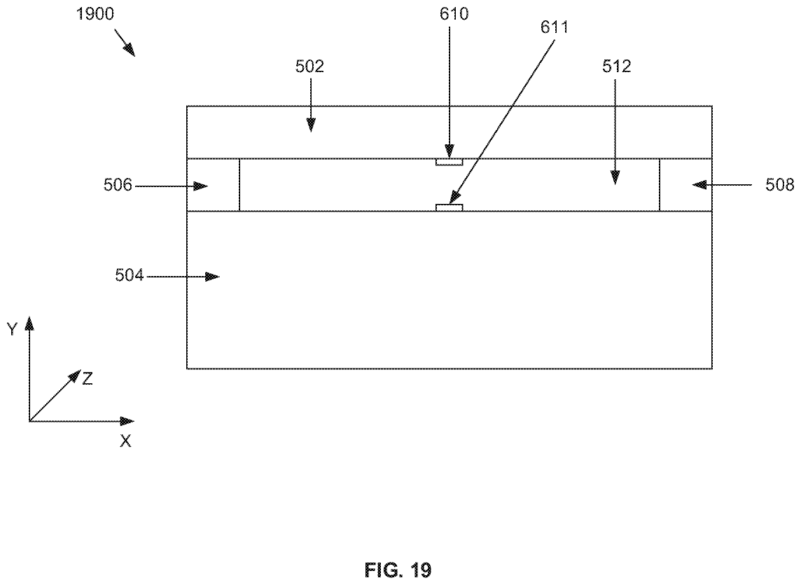

FIG. 19 illustrates an example capacitive micromachined ultrasonic transducer (CMUT) 1900 with the isolation stack bump 610 on the top electrode 502 and the isolation stack bump 611 on the bottom electrode 504. It may be noted that one or both of the top electrode 502 and the bottom electrode 504 may comprise one or more isolation stack bumps 610, 611. Where there is not a matching second bump on the top 502 and bottom 504 electrode for the first bump on the bottom 504 or top 502 electrode, the first bump may be thicker than the bump that does have a matching bump. The sidewalls 506, 508 may define the effective gap (g_{eff}) comprising the bumps 610, 611 and the gap 512.

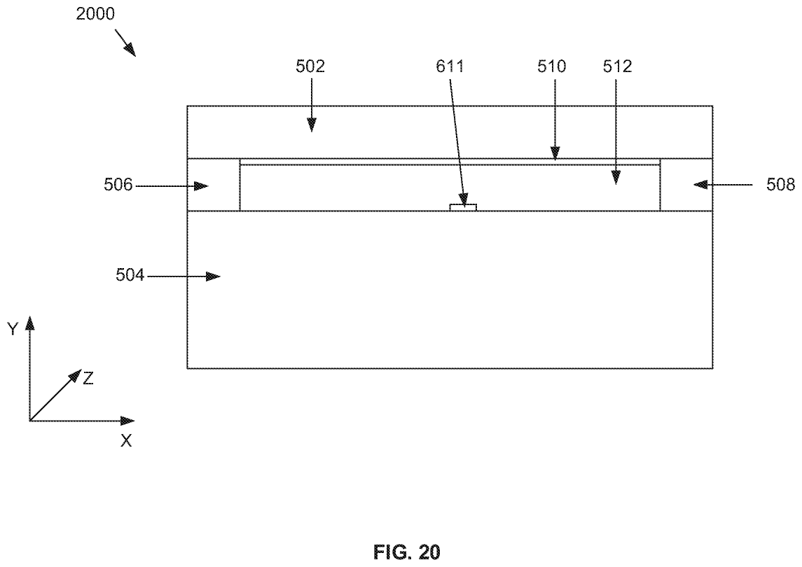

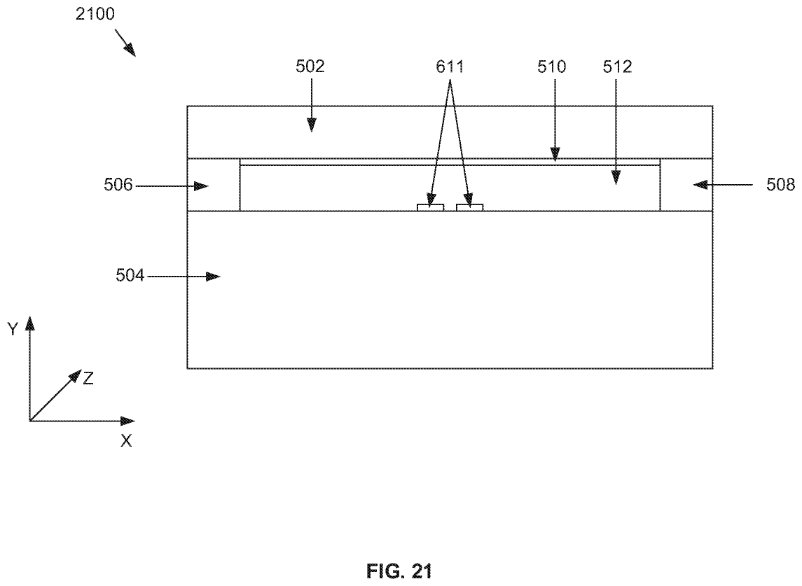

FIGS. 20 and 21 are similar to FIGS. 12 and 16 except that there are one or more isolation stack bumps 611 on the bottom electrode 504 and the isolation stack layer 510 on the top electrode 502. Accordingly, the sidewalls 506, 508 may define the effective gap (g_{eff}) comprising the bump(s) 611, the isolation stack layer 510, and the gap 512.

A CMUT 500G1/500G2, 600, 700, 800, 900-2200 as disclosed may have any geometric shape when viewed from the top (for example, the X-Z plane). As examples, a CMUT 500G1/500G2, 600, 700, 800, 900-2200 may be circular, elliptical, oval, one of the many polygonal shapes, etc. Additionally, while a single bump 610, 611, 710, 810 or multiple bumps 610, 611, 710, 810 may be substantially centered along a direction of a CMUT 500G1/500G2, 600, 700, 800, 900-2200, various embodiments of the disclosure may place a bump 610, 611, 710, 810 or bumps 610, 611, 710, 810 in various positions along a direction of the CMUT 500G1/500G2, 600, 700, 800, 900-2200.

Additionally, while various figures disclosed a surface having either isolation stack layer(s) 510, 511 or isolation stack bump(s) 610, 611, 710, 810, various embodiments of the disclosure may comprise a combination of isolation stack layer(s) 510, 511 and isolation stack bump(s) 610, 611, 710, 810.

Additionally, the top electrode 502 of a CMUT 500G1/500G2, 600, 700, 800, 900-2200 may be perforated, and this may be referred to as a perforated plate. It may be noted that when the top electrode is perforated, the top layer 510 may have corresponding perforations or is placed around the perforations so as to not obstruct the perforations. Similarly, when there are one or more bumps 610, 710, 810 on the top electrode 502, the bump(s) 610, 710, 810 may be placed to not obstruct the perforations.

While various embodiments were disclosed with respect to capacitive micromachined ultrasonic transducers, the disclosure may apply to other types of transducers other than ultrasound transducers. For example, any type of a MEMS device that uses insulation layers may use the disclosed embodiments to solve the problem of charging in one or more insulated layers. Also, while transducers were described in places as being used for medical imaging, various other types of imaging may also make use of the transducers. For example, imaging devices may be used for ultrasound/acoustic sensing, non-destructive evaluation (NDE), ultrasound therapy (High Intensity Focused Ultrasound (HIFU), etc.), etc., in addition to ultrasound imaging of humans, animals, etc.

Aspects of the present disclosure relate to methods and systems for providing a reliable (i.e., defect mitigated) isolation stack 302, 304, 306 in capacitive micromachined ultrasonic transducers (CMUTs) 500G1/500G2, 600, 700, 800, 900-2200. The capacitive micromachined ultrasonic transducer (CMUT) 500G1/500G2, 600, 700, 800, 900-2200 may comprise a top electrode 312, 502 and a bottom electrode 310, 504. The CMUT 500G1/500G2, 600, 700, 800, 900-2200 may comprise a sidewall 314, 506, 508 between the top electrode 312, 502 and the bottom electrode 310, 504. The sidewall 314, 506, 508 is configured to separate the top electrode 312, 502 and the bottom electrode 310, 504 by a gap 320, 512. The CMUT 500G1/500G2, 600, 700, 800, 900-2200 may comprise an isolation stack part 302, 304, 306, 510, 511, 610, 611, 710, 810 on one or both of a bottom side of the top electrode 312, 502 or a top side of the bottom electrode 310, 504. The isolation stack part 302, 304, 306, 510, 511, 610, 611, 710, 810 may comprise a silicon dioxide layer 302, and a partially oxidized silicon nitride comprising a silicon nitride layer 304 and an oxidized nitride layer 306.

In an exemplary embodiment, the isolation stack part 302, 304, 306, 510, 511, 610, 611, 710, 810 comprises one or both of an isolation stack layer 510, 511 that spans substantially a width of the bottom side of the top electrode 312, 502, and an isolation stack layer 510, 511 that spans substantially a width of the top side of the bottom electrode 310, 504. In a representative embodiment, the isolation stack part 302, 304, 306, 510, 511, 610, 611, 710, 810 comprises an isolation stack layer 510, 511 that spans one or both of at least a portion of a width of the bottom side of the top electrode 312, 502, and at least a portion of a width of the top side of the bottom electrode 310, 504. In various embodiments, the isolation stack part 302, 304, 306, 510, 511, 610, 611, 710, 810 comprises one or more isolation stack bumps 610, 611, 710, 810 along one or both of the bottom side of the top electrode 312, 502 or the top side of the bottom electrode 310, 504. In certain embodiments, the one or more isolation stack bumps 610, 611, 710, 810 are substantially centered along a width of the CMUT 500G1/500G2, 600, 700, 800, 900-2200. In an exemplary embodiment, a shape of a cross-section of the one or more isolation stack bumps 610, 611, 710, 810 is one of: rectangular 610, 611, triangular 710, or rounded 810. In a representative embodiment, the one or more isolation stack bumps 610, 611, 710, 810 comprise a first isolation stack bump 610, 710, 810 on the top electrode 312, 502 and a second isolation stack bump 611 on the bottom electrode 310, 504 that is aligned with the first isolation stack bump 610, 710, 810. In various embodiments, the isolation stack part 302, 304, 306, 510, 511, 610, 611, 710, 810 comprises one of one or more isolation stack bumps 610, 611, 710, 810 on a bottom side of the top electrode 312, 502 and an isolation stack layer 510, 511 that spans at least a portion of a width of the top side of the bottom electrode 310, 504, or one or more isolation stack bumps 610, 611, 710, 810 on a top side of the bottom electrode 310, 504 and an isolation stack layer 510, 511 that spans at least a portion of a width of the bottom side of the top electrode 312, 502. In certain embodiments, a thickness of the silicon dioxide layer 302 is approximately 25 nanometers. In an exemplary embodiment, a thickness of the silicon nitride layer 304 is 50-500 nanometers. In a representative embodiment, a thickness of the oxidized nitride layer 306 is at least 4 nanometers. In various embodiments, at least a portion of the isolation stack part 302, 304, 306, 510, 511, 610, 611, 710, 810 is covered with silicon carbide. In certain embodiments, the gap 320, 512 is filled with gas. In an exemplary embodiment, the gap 320, 512 comprises a substantially gas-free vacuum.

Various embodiments provide a method 200, 400 of manufacturing a capacitive micromachined ultrasonic transducer (CMUT) 500G1/500G2, 600, 700, 800, 900-2200. The method 200, 400 may comprise providing 402, 414 a top electrode 312, 502 and a bottom electrode 310, 504. The method 200, 400 may comprise providing 410, 412 a sidewall 314, 506, 508 between the top electrode 312, 502 and the bottom electrode 310, 504. The sidewall 314, 506, 508 is configured to separate the top electrode 312, 502 and the bottom electrode 310, 504 by a gap 320, 512. The method 200, 400 may comprise providing 202-206, 402-406 an isolation stack part 302, 304, 306, 510, 511, 610, 611, 710, 810 on one or both of a bottom side of the top electrode 312, 502 or a top side of the bottom electrode 310, 504. The isolation stack part 302, 304, 306, 510, 511, 610, 611, 710, 810 comprises a silicon dioxide layer 302, and a partially oxidized silicon nitride on the silicon dioxide layer 302, the partially oxidized silicon nitride comprising a silicon nitride layer 304 and an oxidized nitride layer 306.

In a representative embodiment, the method 200, 400 comprises performing a thermal oxidation process 202, 206, 402, 406, 410 to form one or both of the silicon dioxide layer 302 and the oxidized nitride layer 306. In certain embodiments, the method 200, 400 comprises depositing 204, 404 the silicon nitride layer 304 on the silicon dioxide layer 302 by chemical vapor deposition (CVD). In various embodiments, the method 200, 400 comprises covering at least a portion of the isolation stack part with a self-assembled monolayer and/or monolayers of silicon carbide.

Certain embodiments provide a capacitive micromachined ultrasonic transducer (CMUT) 500G1/500G2, 600, 700, 800, 900-2200. The CMUT 500G1/500G2, 600, 700, 800, 900-2200 may comprise a top electrode 312, 502 and a bottom electrode 310, 504. The CMUT 500G1/500G2, 600, 700, 800, 900-2200 may comprise a sidewall 314, 506, 508 between the top electrode 312, 502 and the bottom electrode 310, 504. The sidewall 314, 506, 508 is configured to separate the top electrode 312, 502 and the bottom electrode 310, 504 by a gap 320, 512. The CMUT 500G1/500G2, 600, 700, 800, 900-2200 may comprise an isolation stack part 302, 304, 306, 510, 511, 610, 611, 710, 810 on one or both of a bottom side of the top electrode 312, 502 or a top side of the bottom electrode 310, 504. The isolation stack part 302, 304, 306, 510, 511, 610, 611, 710, 810 comprises a silicon dioxide layer 302 having a thickness of approximately 25 nanometers, and a partially oxidized silicon nitride on the silicon dioxide layer 302, the partially oxidized silicon nitride comprising a silicon nitride layer 304 and an oxidized nitride layer 306. A thickness of the oxidized nitride layer 306 is at least 4 nanometers.

In various embodiments, the isolation stack part 302, 304, 306, 510, 511, 610, 611, 710, 810 comprises one of an isolation stack layer 510, 511 or an isolation stack bump 610, 611, 710, 810.

As utilized herein the term “circuitry” refers to physical electronic components (i.e. hardware) and any software and/or firmware (“code”) which may configure the hardware, be executed by the hardware, and or otherwise be associated with the hardware. As used herein, for example, a particular processor and memory may comprise a first “circuit” when executing a first one or more lines of code and may comprise a second “circuit” when executing a second one or more lines of code. As utilized herein, “and/or” means any one or more of the items in the list joined by “and/or”. As an example, “x and/or y” means any element of the three-element set {(x), (y), (x, y)}. As another example, “x, y, and/or z” means any element of the seven-element set {(x), (y), (z), (x, y), (x, z), (y, z), (x, y, z)}. As utilized herein, the term “exemplary” means serving as a non-limiting example, instance, or illustration. As utilized herein, the terms “e.g.,” and “for example” set off lists of one or more non-limiting examples, instances, or illustrations. As utilized herein, circuitry is “operable” and/or “configured” to perform a function whenever the circuitry comprises the necessary hardware and code (if any is necessary) to perform the function, regardless of whether performance of the function is disabled, or not enabled, by some user-configurable setting.

While the present disclosure has been described with reference to certain embodiments, it will be understood by those skilled in the art that various changes may be made and equivalents may be substituted without departing from the scope of the present disclosure. In addition, many modifications may be made to adapt a particular situation or material to the teachings of the present disclosure without departing from its scope. Therefore, it is intended that the present disclosure not be limited to the particular embodiment disclosed, but that the present disclosure will include all embodiments falling within the scope of the appended claims.

What is claimed:

1. A capacitive micromachined ultrasonic transducer (CMUT), comprising:
a top electrode and a bottom electrode;
a sidewall between the top electrode and the bottom electrode, wherein the sidewall is configured to separate the top electrode and the bottom electrode by a gap; and
an isolation stack part on one or both of a bottom side of the top electrode or a top side of the bottom electrode, wherein the isolation stack part comprises:
a silicon dioxide layer; and
a partially oxidized silicon nitride comprising a silicon nitride layer and an oxidized nitride layer.

2. The CMUT of claim 1, wherein the isolation stack part comprises one or both of:
an isolation stack layer that spans substantially a width of the bottom side of the top electrode; and
an isolation stack layer that spans substantially a width of the top side of the bottom electrode.

3. The CMUT of claim 1, wherein the isolation stack part comprises an isolation stack layer that spans one or both of:
at least a portion of a width of the bottom side of the top electrode; and
at least a portion of a width of the top side of the bottom electrode.

4. The CMUT of claim 1, wherein the isolation stack part comprises one or more isolation stack bumps along one or both of the bottom side of the top electrode or the top side of the bottom electrode.

5. The CMUT of claim 4, wherein the one or more isolation stack bumps are substantially centered along a width of the CMUT.

6. The CMUT of claim 4, wherein a shape of a cross-section of the one or more isolation stack bumps is one of: rectangular, triangular, or rounded.

7. The CMUT of claim 4, wherein the one or more isolation stack bumps comprise a first isolation stack bump on the top electrode and a second isolation stack bump on the bottom electrode that is aligned with the first isolation stack bump.

8. The CMUT of claim 1, wherein the isolation stack part comprises one of:
one or more isolation stack bumps on a bottom side of the top electrode and an isolation stack layer that spans at least a portion of a width of the top side of the bottom electrode; or
one or more isolation stack bumps on a top side of the bottom electrode and an isolation stack layer that spans at least a portion of a width of the bottom side of the top electrode.

9. The CMUT of claim 1, wherein a thickness of the silicon dioxide layer is approximately 25 nanometers.

10. The CMUT of claim 1, wherein a thickness of the silicon nitride layer is 50-500 nanometers.

11. The CMUT of claim 1, wherein a thickness of the oxidized nitride layer is at least 4 nanometers.

12. The CMUT of claim 1, wherein at least a portion of the isolation stack part is covered with silicon carbide.

13. The CMUT of claim 1, wherein the gap is filled with gas.

14. The CMUT of claim 1, wherein the gap comprises a substantially gas-free vacuum.

15. A method of manufacturing a capacitive micromachined ultrasonic transducer (CMUT), the method comprising:
providing a top electrode and a bottom electrode;
providing a sidewall between the top electrode and the bottom electrode, wherein the sidewall is configured to separate the top electrode and the bottom electrode by a gap; and
providing an isolation stack part on one or both of a bottom side of the top electrode or a top side of the bottom electrode, wherein the isolation stack part comprises:
a silicon dioxide layer; and
a partially oxidized silicon nitride on the silicon dioxide layer, the partially oxidized silicon nitride comprising a silicon nitride layer and an oxidized nitride layer.

16. The method of claim 15, comprising performing a thermal oxidation process to form one or both of the silicon dioxide layer and the oxidized nitride layer.

17. The method of claim 15, comprising depositing the silicon nitride layer on the silicon dioxide layer by chemical vapor deposition (CVD).

18. The method of claim 15, comprising covering at least a portion of the isolation stack part with a self-assembled monolayer and/or monolayers of silicon carbide.

19. A capacitive micromachined ultrasonic transducer (CMUT), comprising:
a top electrode and a bottom electrode;
a sidewall between the top electrode and the bottom electrode, wherein the sidewall is configured to separate the top electrode and the bottom electrode by a gap; and
an isolation stack part on one or both of a bottom side of the top electrode or a top side of the bottom electrode, wherein the isolation stack part comprises:
a silicon dioxide layer having a thickness of approximately 25 nanometers; and
a partially oxidized silicon nitride on the silicon dioxide layer, the partially oxidized silicon nitride comprising a silicon nitride layer and an oxidized nitride layer, wherein a thickness of the oxidized nitride layer is at least 4 nanometers.

20. The CMUT of claim 19, wherein the isolation stack part comprises one of an isolation stack layer or an isolation stack bump.
